(19) United States
(12) Patent Application Publication
(10) Pub. No.: US 2025/0311218 A1
(43) Pub. Date: Oct. 2, 2025

(54) METHODS OF FORMING MICROELECTRONIC DEVICES INCLUDING AIR GAP, AND RELATED ELECTRONIC DEVICES AND SYSTEMS

(71) Applicant: Micron Technology, Inc., Boise, ID (US)

(72) Inventors: Maryam Sayyah, Boise, ID (US); Jiewei Chen, Meridian, ID (US); Fatma Arzum Simsek-Ege, Boise, ID (US)

(21) Appl. No.: 19/067,485

(22) Filed: Feb. 28, 2025

Related U.S. Application Data
(60) Provisional application No. 63/571,979, filed on Mar. 29, 2024.

(51) Int. Cl. H10B 43/27; H10B 41/10; H10B 41/27; H10B 41/35; H10B 41/50; H10B 43/10; H10B 43/35; H10B 43/50; H10D 62/10

(52) U.S. Cl. CPC H10B 43/27; H10B 41/10; H10B 41/27; H10B 41/35; H10B 41/50; H10B 43/10; H10B 43/35; H10B 43/50; H10D 62/115

(57) ABSTRACT

An electronic device comprises a first stack, a second stack structure adjacent to the first stack structure, a third stack structure adjacent to the second stack structure, a first pillar structure extending vertically through the first stack structure, a second pillar structure extending vertically through the second stack structure, a third pillar structure extending through the third stack structure, an inter-block pillar structure extending vertically through the first, second and third stack structures, and an isolation structure extending vertically through at least a portion of the third stack structure. Each of the first, second and third stack structures comprises tiers of vertically alternating conductive structures and insulative structures. The first and second pillar structures comprise strings of memory cells. The inter-block pillar structure segments the first, second and third stack structures into blocks. The isolation structure comprises an air gap therein and segments the blocks into sub-blocks. Related methods are also described.

### CROSS-REFERENCE TO RELATED APPLICATIONS

This application claims the benefit under 35 U.S.C. § 119 (e) of U.S. Provisional Patent Application Ser. No. 63/571,979, filed Mar. 29, 2024, the disclosure of which is hereby incorporated herein in its entirety by this reference.

### TECHNICAL FIELD

Embodiments disclosed herein relate to the field of electronic device design and fabrication. More particularly, embodiments of the disclosure relate to methods of forming microelectronic devices including air gaps, and to related electronic devices and systems.

### BACKGROUND

A continuing goal of the electronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more stack structures including tiers of conductive structures and insulative structures. Each vertical memory string may include at least one select device coupled in series to a serial combination of vertically-stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive structures of the tiers of the stack structure(s) of the memory device and access lines (e.g., word lines) so that the memory cells of the vertical memory array can be uniquely selected for writing, reading, or erasing operations.

As vertical memory array technology has advanced, additional memory density has been provided by forming vertical memory arrays to include stacks comprising additional tiers of conductive structures. As the number of tiers of the conductive structures increases, processing conditions of the formation of aligned contacts to various components of an electronic device become increasingly difficult. In addition, other technologies to increase memory density have reduced the spacing between adjacent vertical memory strings.

### BRIEF DESCRIPTION OF THE DRAWINGS

FIGS. 1 through 4 are simplified partial cross-sectional views illustrating a method of forming a microelectronic device, in accordance with embodiments of the disclosure;

FIGS. 1A, 3A and 4A are enlarged views of the area labeled “A” in FIGS. 1, 3 and 4, respectively;

FIG. 5 is a simplified partial top-down view of a microelectronic device of FIG. 4, in accordance with embodiments of the disclosure;

FIG. 6 is a partial cutaway perspective view of an electronic device, in accordance with embodiments of the disclosure;

FIG. 7 is a block diagram of an electronic system, in accordance with embodiments of the disclosure; and

FIG. 8 is a block diagram of a processor-based system, in accordance with embodiments of the disclosure.

### DETAILED DESCRIPTION

Electronic devices (e.g., microelectronic devices) according to embodiments of the disclosure include conductive structures segmenting the electronic device into blocks and isolation structures segmenting the blocks into sub-blocks are disclosed. The conductive structures extend vertically through the stacked structure (i.e., through the first stack structure, the second stack structure, and the third stack structure). The isolation structure comprises an air gap (e.g., a void) therein. The electronic device includes a stacked structure composed of a first stack structure adjacent to a source structure, a second stack structure overlying the first stack structure, and a third stack structure (e.g., a select gate drain stack structure) overlying the second stack structure. Each of the stack structures comprises tiers of vertically alternating conductive structures and insulative structures. Strings of memory cells extend vertically through the first stack structure and the second stack structure. The strings of memory cells individually comprise a channel material extending vertically through the first stack structure and the second stack structure. Conductive pillar structures extend through the third stack structure and adjacent to the strings of memory cells. The isolation structures extend vertically through at least a portion of the third stack structure, and laterally intervene between neighboring conductive pillar structures. The electronic device further comprises conductive contacts vertically interposed between the strings of memory cells and the conductive pillar structures.

During formation of the electronic device, openings may be formed adjacent to neighboring conductive pillar structures and extending through at least a portion of the third stack structure. The openings may be non-conformally filled with at least one dielectric material to form the isolation structures that segment the electronic device into sub-blocks. The isolation structures comprise an air gap therein. The air gap may represent at least about 50% by volume, such as more than about 50% by volume, more than about 60% by volume, of the isolation structure. Air has a lower dielectric constant value than conventional dielectric materials (e.g., silicon oxide, silicon nitride), thus enabling the electronic device according to embodiments of the disclosure to have the isolation structures with smaller critical dimensions. In other words, the isolation structure comprising an air gap therein may provide a higher level of isolation (e.g., electrical isolation) between sub-blocks of the electronic device compared to isolation structures comprised entirely of dielectric materials (e.g., without any air gap therein). This allows for the fabrication of electronic devices with isolation structures having smaller critical dimensions (e.g., smaller horizontal footprint) to increase the memory density of the electronic device.

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional electronic device fabrication techniques employed in the industry. In addition, the description provided below does not form a complete process flow for manufacturing an electronic device (e.g., a memory device, such as 3D NAND Flash memory device). The structures described below do not form a complete electronic device. Only those process acts and structures necessary to understand the embodiments of the disclosure are described in detail below. Additional acts to form a complete electronic device from the structures may be performed by conventional fabrication techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Stated another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “air gap” means and includes a void between adjacent structures or features. The air gap may be empty of a solid material and/or liquid material. The void is not necessarily devoid of a material within its boundaries and may, for example, contain a gaseous species, such as air or an inert gas, or a vacuum.

As used herein, the term “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, the term “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “conductive material” means and includes an electrically conductive material. The conductive material may include one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, a “conductive structure” means and includes a structure formed of and including one or more conductive materials.

As used herein, “insulative material” and “dielectric material” mean and include an electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, an “insulative structure” means and includes a structure formed of and including an insulative material.

As used herein, a “dielectric structure” means and includes a structure formed of and including one or more dielectric materials.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

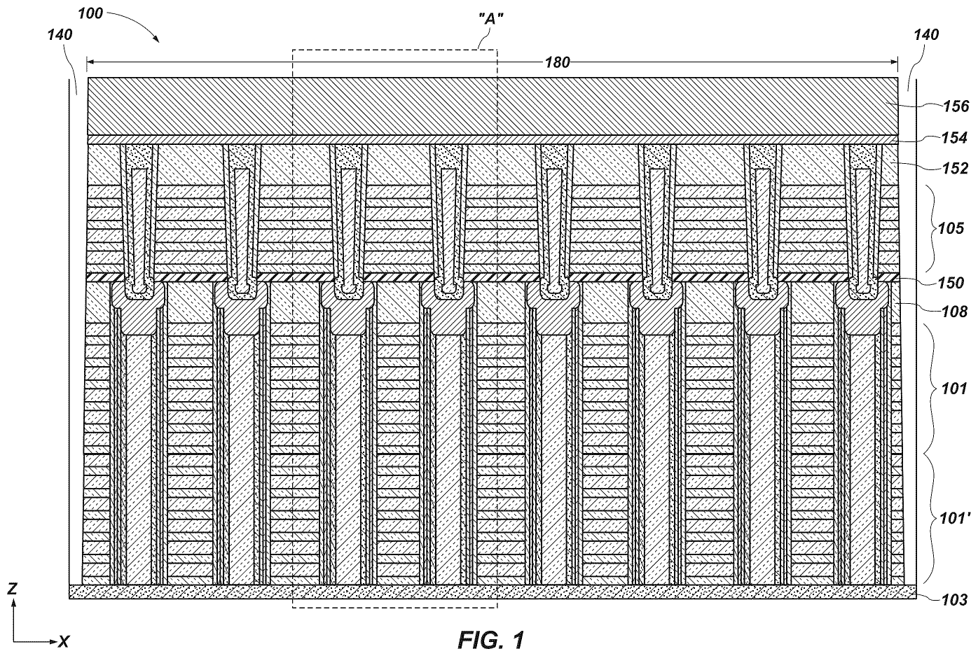

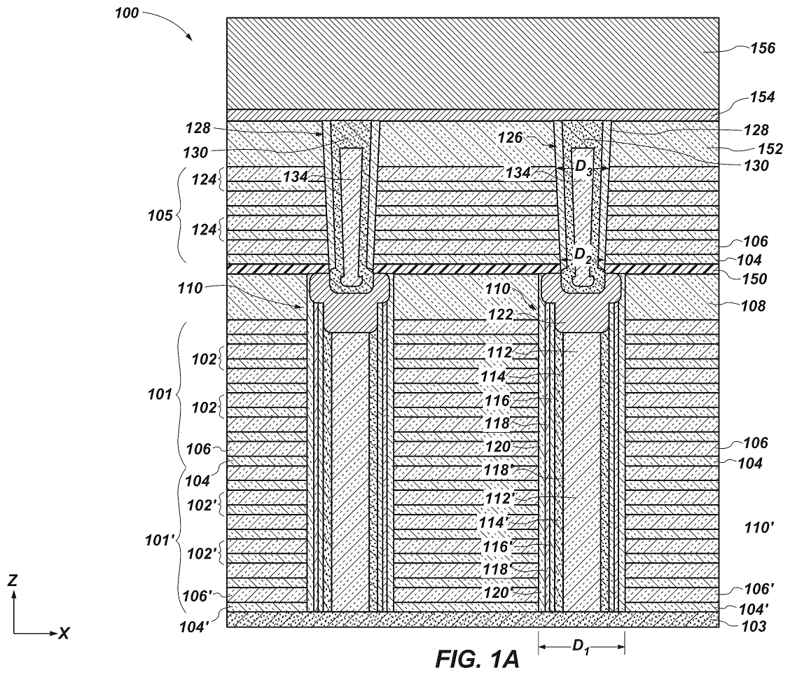

FIGS. 1 through 4 illustrate a method of forming a microelectronic device in accordance with embodiments of the disclosure. For convenience in describing FIGS. 1 through 4, a first horizontal direction may be defined as the X-direction and a second horizontal direction, which is transverse (e.g., perpendicular) to the first horizontal direction, as the Y-direction. A third direction, which is transverse (e.g., perpendicular) to each of the first horizontal direction and the second horizontal direction, may be defined as the Z-direction (i.e., vertical direction).

As shown in FIG. 1, an electronic device 100 may be formed to include a stacked structure composed of a first stack structure 101′ overlying a source 103 (e.g., a source tier, a source plate), a second stack structure 101 overlying the first stack structure 101′, and a third stack structure 105 overlying the second stack structure 101. The electronic device 100 further includes a dielectric material 108 between the second stack structure 101 and the third stack structure 105; an upper insulative material 152 over the third stack structure 105; a barrier material 154 over the upper insulative material 152; an uppermost insulative material 156 overlying the barrier material 154; and slots 140 extending through the first stack structure 101′, the second stack structure 101, and the third stack structure 105. The electronic device 100 may include an etch stop material 150 between the dielectric material 108 and the third stack structure 105. The electronic device 100 at the process stage shown in FIG. 1 may be formed by conventional techniques.

FIG. 1A is an enlarged view of the area labeled “A” in FIG. 1. As shown in FIG. 1A, the first stack structure 101′ includes a vertically (e.g., in the Z-direction) alternating sequence of insulative structures 104′ and sacrificial insulative structures 106′ arranged in tiers 102′. Each of the tiers 102′ may individually include an insulative structure 104′ directly vertically neighboring (e.g., adjacent) the sacrificial insulative structures 106′. The second stack structure 101 includes a vertically (e.g., in the Z-direction) alternating sequence of insulative structures 104 and sacrificial insulative structures 106 arranged in tiers 102. Each of the tiers 102 may individually include an insulative structure 104 directly vertically neighboring (e.g., adjacent) the sacrificial insulative structures 106.

The insulative structures 104, 104′ of the tiers 102, 102′ may be formed of and include, for example, at least one dielectric material, such as one or more of an oxide material (e.g., silicon dioxide), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃). In some embodiments, the insulative structures 104, 104′ are formed of and include silicon dioxide.

The sacrificial insulative structures 106, 106′ may be formed of and include an insulative material that is different than, and exhibits an etch selectivity with respect to, the insulative structures 104, 104′. In some embodiments, the sacrificial insulative structures 106, 106′ are formed of and include a nitride material (e.g., silicon nitride) or an oxynitride material (e.g., silicon oxynitride). In some embodiments, the sacrificial insulative structures 106, 106′ comprise silicon nitride.

In some embodiments, a number (e.g., quantity) of tiers 102′ of the first stack structure 101′ may be in a range of from about 32 to about 256 of the tiers 102′. In some embodiments, the first stack structure 101′ includes 128 of the tiers 102′. However, the disclosure is not so limited, and the first stack structure 101′ may include a different number of the tiers 102′.

In some embodiments, a number (e.g., quantity) of tiers 102 of the second stack structure 101 may be in a range of from about 32 to about 256 of the tiers 102. In some embodiments, the second stack structure 101 includes 128 of the tiers 102. However, the disclosure is not so limited, and the second stack structure 101 may include a different number of the tiers 102.

Although FIG. 1 and FIG. 1A have been described and illustrated as including first stack structure 101′ directly over the source 103, the disclosure is not so limited. In other embodiments, the first stack structure 101′ overlies another stack structure comprising additional tiers 102″ of the insulative structures 104″ and the sacrificial insulative structures 106″.

Furthermore, the third stack structure 105 may include a different number of tiers 124 than that shown in FIG. 1 and FIG. 1A.

The source 103 may be formed of and include, for example, a semiconductor material doped with one or more p-type conductivity materials (e.g., polysilicon doped with at least one p-type dopant, such as one or more of boron, aluminum, and gallium) or one or more n-type conductivity materials (e.g., polysilicon doped with at least one n-type dopant, such as one or more of arsenic, phosphorous, antimony, and bismuth).

The dielectric material 108 may be located over an uppermost one of the tiers 102 of the second stack structure 101. The dielectric material 108 may be formed of and include an electrically insulative material, such as, for example, one or more of phosphosilicate glass (PSG), borosilicate glass (BSG), fluorosilicate glass (FSG), borophosphosilicate glass (BPSG), and silicon dioxide. In some embodiments, the dielectric material 108 comprises the same material composition as the insulative structures 104. In some embodiments, the dielectric material 108 comprises silicon dioxide.

The electronic device 100 may include first pillar structure 110′ (e.g., cell pillars, memory pillars) of materials vertically extending (e.g., in the Z-direction) through the first stack structure 101′. The materials of the first pillar structure 110′ may form memory cells (e.g., strings of memory cells). The materials of the first pillar structure 110′ may be formed by conventional techniques. The first pillar structure 110′ may each individually comprise an insulative material 112′, a channel material 114′ horizontally neighboring the insulative material 112′, a tunnel dielectric material 116′ horizontally neighboring the channel material 114′, a memory material 118′ horizontally neighboring the tunnel dielectric material 116′, and a dielectric charge blocking material 120′ horizontally neighboring the memory material 118′. The dielectric charge blocking material 120′ may be horizontally neighboring one of the sacrificial insulative structures 106′ of one of the tiers 102′ of the first stack structure 101′. The channel material 114′ may be horizontally interposed between the insulative material 112′ and the tunnel dielectric material 116′; the tunnel dielectric material 116′ may be horizontally interposed between the channel material 114′ and the memory material 118′; the memory material 118′ may be horizontally interposed between the tunnel dielectric material 116′ and the dielectric charge blocking material 120′; and the dielectric charge blocking material 120′ may be horizontally interposed between the memory material 118′ and the sacrificial insulative structure 106′.

The electronic device 100 may further include second pillar structure 110 (e.g., cell pillars, memory pillars) of materials vertically extending (e.g., in the Z-direction) through the second stack structure 101. The materials of the second pillar structure 110 may form memory cells (e.g., strings of memory cells). The second pillar structure 110 may each individually comprise an insulative material 112, a channel material 114 horizontally neighboring the insulative material 112, a tunnel dielectric material 116 horizontally neighboring the channel material 114, a memory material 118 horizontally neighboring the tunnel dielectric material 116, and a dielectric charge blocking material 120 horizontally neighboring the memory material 118. The dielectric charge blocking material 120 may be horizontally neighboring one of the sacrificial insulative structures 106 of one of the tiers 102 of the second stack structure 101.

The insulative materials 112, 112′ may be formed of and include an electrically insulative material such as, for example, phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material (e.g., silicon nitride), an oxynitride (e.g., silicon oxynitride), a dielectric carbon nitride material (e.g., silicon carbon nitride), a dielectric carboxynitride material (e.g., silicon carboxynitride), or combinations thereof. In some embodiments, the insulative materials 112, 112′ comprise silicon dioxide.

The channel materials 114, 114′ may be formed of and include one or more of a semiconductor material and an oxide semiconductor material. Non-limiting examples of the semiconductor material include an elemental semiconductor material (e.g., polycrystalline silicon); a III-V compound semiconductor; a II-VI compound semiconductor material; an organic semiconductor material; GaAs; InP; GaP; GaN, or any other semiconductor materials. In some embodiments, the channel materials 114, 114′ includes amorphous silicon or polysilicon. In some embodiments, the channel materials 114, 114′ comprises a doped semiconductor material.

The tunnel dielectric materials 116, 116′ may be formed of and include a dielectric material through which charge tunneling can be performed under suitable electrical bias conditions, such as through hot-carrier injection or by Fowler-Nordheim tunneling induced charge transfer. By way of non-limiting example, the tunnel dielectric materials 116, 116′ may be formed of and include one or more of silicon oxide, silicon nitride, silicon oxynitride, dielectric metal oxides (such as aluminum oxide and hafnium oxide), dielectric metal oxynitride, dielectric metal silicates, alloys thereof, or combinations thereof. In some embodiments, the tunnel dielectric materials 116, 116′ comprises silicon dioxide. In other embodiments, the tunnel dielectric materials 116, 116′ comprises silicon oxynitride.

The memory materials 118, 118′ may comprise a charge trapping material or a conductive material. The memory materials 118, 118′ may be formed of and include one or more of silicon nitride, silicon oxynitride, polysilicon (doped polysilicon), a conductive material (e.g., tungsten, molybdenum, tantalum, titanium, platinum, ruthenium, alloys thereof, or a metal silicide such as tungsten silicide, molybdenum silicide, tantalum silicide, titanium silicide, nickel silicide, cobalt silicide, or a combination thereof), a semiconductive material polycrystalline or amorphous semiconductor material including at least one elemental semiconductor element or at least one compound semiconductor material, conductive nanoparticles (e.g., ruthenium nanoparticles), metal dots. In some embodiments, the memory materials 118, 118′ comprises silicon nitride.

The dielectric charge blocking materials 120, 120′ may be formed of and include a dielectric material such as, for example, one or more of an oxide (e.g., silicon dioxide), a nitride (silicon nitride), and an oxynitride (silicon oxynitride), or other materials. In some embodiments, the dielectric charge blocking materials 120, 120′ comprises silicon oxynitride.

In some embodiments the tunnel dielectric material 116′, the memory material 118′, and the dielectric charge blocking material 120′ of the first pillar structure 110′ together may comprise a structure configured to trap a charge, such as, for example, an oxide-nitride-oxide (ONO) structure. In some such embodiments, the tunnel dielectric material 116′ comprises silicon dioxide, the memory material 118′ comprises silicon nitride, and the dielectric charge blocking material 120′ comprises silicon dioxide.

In some embodiments the tunnel dielectric material 116, the memory material 118, and the dielectric charge blocking material 120 of the second pillar structure 110 together may comprise a structure configured to trap a charge, such as, for example, an oxide-nitride-oxide (ONO) structure. In some such embodiments, the tunnel dielectric material 116 comprises silicon dioxide, the memory material 118 comprises silicon nitride, and the dielectric charge blocking material 120 comprises silicon dioxide.

After forming the second pillar structures 110, a portion of the second pillar structures 110 may be removed to recess the first pillar structures 110′ relative to an uppermost surface of the dielectric material 108. In some embodiments, a portion of the insulative material 112 and the channel material 114 of the second pillar structures 110 may be recessed vertically lower (e.g., in the Z-direction) than the other components of the of the second pillar structures 110 (e.g., the tunnel dielectric material 116, the memory material 118, the dielectric charge blocking material 120). In some embodiments, a conductive material 122 may be formed within the recesses to form a so-called “conductive plug structure.” The conductive material 122 may be formed of and include, a polysilicon or another material formulated to exhibit an etch selectivity with respect to the material of the dielectric material 108 and, in some embodiments, with respect to one or more of the materials of the second pillar structures 110. In some embodiments, the conductive material 122 is electrically connected to (e.g., in electrical communication with) the channel material 114. In some embodiments, the conductive material 122 comprises doped polysilicon. In some embodiments, the conductive material 122 is doped with one or more n-type dopants such as, for example, phosphorus. In some embodiments, the conductive material 122 is lightly doped (e.g., at a concentration of about 1×10¹⁸ atoms/cm³). The conductive material 122 may comprise sharp corners or, alternatively, the conductive material 122 may comprise rounded corners. After forming the conductive material 122, the electronic device 100 may be exposed to, for example, a chemical mechanical planarization (CMP) process to remove conductive material 122 from outside surfaces of the recesses such as those on an upper surface of the dielectric material 108.

After the formation of the conductive material 122, a third stack structure 105 (e.g., a select gate drain stack structure) may be formed over the second stack structure 101. The third stack structure 105 may include a vertically alternating sequence of additional insulative structures 104 and additional sacrificial insulative structures 106 formed over an optional etch stop material 150. The additional insulative structures 104 and the additional sacrificial insulative structures 106 may be arranged in tiers 124. The third stack structure 105 may include an upper insulative material 152 having a greater thickness in a vertical direction (e.g., in the Z-direction) than the additional insulative structures 104 of the third stack structure 105.

The etch stop material 150, if present, may be formed of and include, for example, a material exhibiting an etch selectivity with respect to the insulative structures 104 and the sacrificial insulative structures 106. In some embodiments, the electronic device 100 may not include the etch stop material 150 between the second stack structure 101 and the third stack structure 105. In some such embodiments, the dielectric material 108 (e.g., alone) may intervene between the second stack structure 101 and the third stack structure 105.

With continued reference to FIG. 1A, the electronic device 100 may include third pillar structures 126 vertically extending (e.g., in the Z-direction) through the third stack structure 105. At least some (e.g., each) of the third pillar structures 126 are substantially horizontally aligned (e.g., are concentric) with the second pillar structures 110. For example, a central axis of each of the third pillar structures 126 may be substantially horizontally aligned (e.g., in each of the X-direction and the Y-direction) relative to a central axis of the vertically underlying second pillar structures 110. The third pillar structures 126 may extend into the conductive material 122, and horizontal boundaries (e.g., lateral edges) of the third pillar structures 126 may not extend beyond horizontal boundaries (e.g., lateral edges) of the underlying second pillar structures 110.

The third pillar structures 126 may each individually include a liner material 128, a channel material 130 horizontally neighboring the liner material 128, and an insulative material 134 horizontally neighboring the channel material 130. The liner material 128 may be horizontally neighboring the additional sacrificial insulative structures 106 of the tiers 124 of the third stack structure 105. The channel material 130 may be horizontally interposed between the liner material 128 and the insulative material 134. The insulative material 134 may also vertically overlie (e.g., in the Z-direction) the channel material 130, such as a horizontally extending portion of the channel material 130 over the conductive material 122.

The liner material 128 may be formed of and include, for example, an insulative material, such as one or more of the materials described above with reference to the insulative material 112. In some embodiments, the liner material 128 comprises silicon dioxide.

The channel material 130 of the third pillar structures 126 may be in electrical communication with the channel material 114 of the second pillar structures 110 through the conductive material 122. The channel material 130 may comprise one or more of the materials described above with reference to the channel material 114. In some embodiments, the channel material 130 comprises the same material composition as the channel material 114. Since the channel material 130 may comprise the same material composition as the channel material 114 and the channel material 130 is in electrical communication with the channel material 114 through the conductive material 122, as used herein, the channel material 114, the conductive material 122, and the channel material 130 may be collectively referred to as a channel region of the electronic device 100. The channel material 130 may comprise sharp corners or, alternatively, the channel material 130 may comprise rounded corners.

The insulative material 134 may be formed of and include one or more of the materials described above with reference to the insulative material 112. In some embodiments, the insulative material 134 comprises substantially the same material composition as the insulative material 112. In some embodiments, the insulative material 134 comprises silicon dioxide.

The barrier material 154 (e.g., an etch stop material) may be formed over the upper insulative material 152 and the third pillar structure 126. In some embodiments, the upper insulative material 152 comprises the same material composition as the dielectric material 108. In some embodiments, the upper insulative material 152 comprises silicon dioxide. In some embodiments, the barrier material 154 comprises substantially the same material composition as the etch stop material 150. In other embodiments, the barrier material 154 comprises a nitride material (e.g., silicon nitride, silicon oxynitride material, silicon oxycarbonitride material), although other materials may be contemplated, so long as the barrier material 154 exhibits etch selectivity relative to surrounding materials. In some embodiments, the barrier material 154 may be formed of and include silicon oxycarbonitride (SiOCN).

The uppermost insulative material 156 may be formed adjacent to (e.g., on or over) the barrier material 154. While FIG. 1A illustrates the uppermost insulative material 156 as a single material for convenience, multiple materials may be present. For example, the uppermost insulative material 156 may be formed to include a first uppermost insulative material adjacent to (e.g., on or over) the barrier material 154, and a second uppermost insulative material adjacent to (e.g., on or over) the first uppermost insulative material, collectively referred to herein as the uppermost insulative material 156.

The uppermost insulative material 156 may be formed of and include at least one dielectric material. In some embodiments, the uppermost insulative material 156 is formed of and includes silicon dioxide (SiO₂). A material composition of the uppermost insulative material 156 may be substantially the same as or different than a material composition of the insulative structures 104 of the second stack structure 101 and the third stack structure 105. The uppermost insulative material 156 and the upper insulative material 152 are separated from one another by the barrier material 154.

As shown in FIG. 1A, an outer horizontal dimension of the first pillar structure 110′ and the second pillar structure 110 may be relatively larger than an outer horizontal dimension of the third pillar structure 126. For example, a dimension D₁ (e.g., a diameter) of the first pillar structure 110′ and the second pillar structure 110 may be within a range from about 90 nm to about 150 nm, such as from about 90 nm to about 100 nm, from about 100 nm to about 110 nm, from about 110 nm to about 120 nm, from about 120 nm to about 130 nm, from about 130 nm to about 140 nm, or from about 140 nm to about 150 nm. In some embodiments, the dimension D₁ is about 120 nm. However, the disclosure is not so limited and the dimension D₁ may be different than those described. An outer dimension D₂ (e.g., a diameter) of a lower portion of the third pillar structure 126 may be within a range from about 30 nm to about 120 nm, such as from about 30 nm to about 40 nm, from about 40 nm to about 60 nm, from about 60 nm to about 80 nm, from about 80 nm to about 100 nm, or from about 100 nm to about 120 nm. In some embodiments, the dimension D₂ may be within a range from about 50 nm to about 60 nm, such as about 55 nm. In addition, an outer dimension D₃ (e.g., a diameter) of an upper portion of the third pillar structure 126 may be within a range from about 50 nm to about 140 nm, such as from about 50 nm to about 60 nm, from about 60 nm to about 80 nm, from about 80 nm to about 100 nm, from about 100 nm to about 120 nm, or from about 120 nm to about 140 nm. In some embodiments, the dimension D₃ is from about 65 nm to about 75 nm, such as about 70 nm. In some embodiments, the dimension D₃ is larger than the dimension D₂ and sidewalls of the third pillar structure 126 may exhibit a tapered (e.g., sloped) shape with respect to a major surface of the source 103. In some embodiments, the dimension D₁ of the first pillar structure 110′ and the second pillar structure 110 is about twice as large as the dimension D₃ of the third pillar structure 126. Horizontal (e.g., lateral) boundaries of the third pillar structure 126 may not extend beyond horizontal boundaries of the first pillar structure 110′ and the second pillar structure 110. In other words, the dimension D₃ may be sized such that the third pillar structure 126 does not laterally extend beyond the horizontal boundary of the first pillar structure 110′ and the second pillar structure 110.

Referring to FIG. 1, the electronic device 100 includes slots 140 extending vertically through the first stack structure 101′, the second stack structure 101, and the third stack structure 105. The slots 140 may be referred to herein as so-called “replacement gate” slots. The slots 140 may be formed by removing portions of the materials of the uppermost insulative material 156, the barrier material 154, the upper insulative material 152, the third stack structure 105, the etch stop material 150 (if any), the dielectric material 108, the second stack structure 101, and the first stack structure 101′, for example, by one or more etch processes. In some embodiments, the slots 140 expose at least a portion of the source 103. The electronic device 100 may be divided into blocks 180 between horizontally neighboring slots 140 (e.g., in the X-direction). Although FIG. 1 illustrates only a portion of one block 180, it will be understood that the electronic device 100 includes several blocks 180.

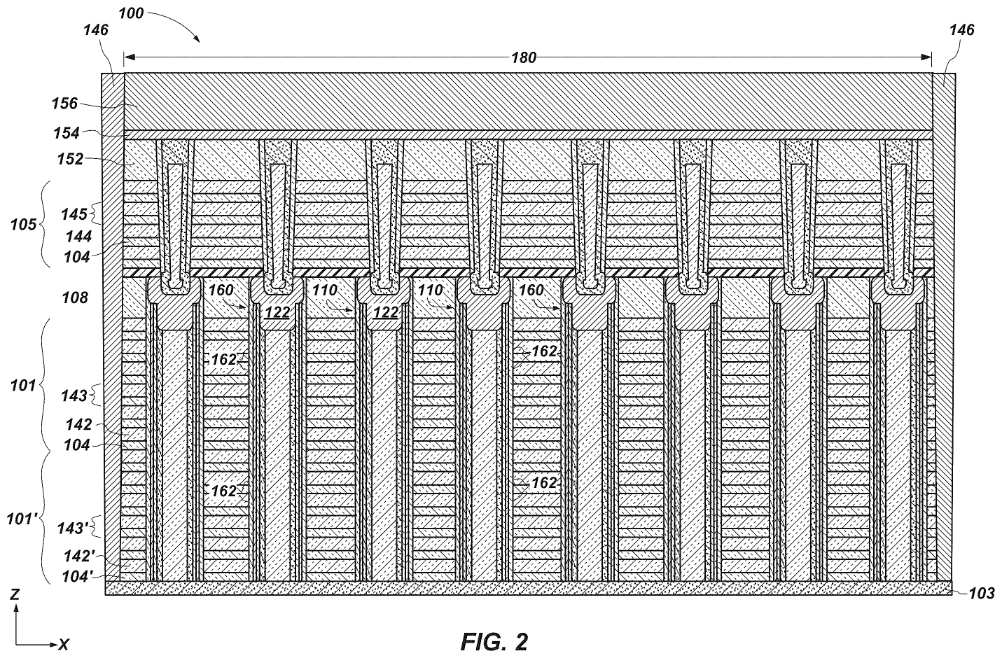

Referring to FIG. 2, after forming the slots 140 (FIG. 1), the sacrificial insulative structures 106, 106′ (FIG. 1) of the first stack structures 101′ and the second stack structures 101 may be removed through the slots 140 as part of a so-called “replacement gate” or “gate last” process. By way of non-limiting example, the sacrificial insulative structures 106, 106′ may be removed by exposing the sacrificial insulative structures 106, 106′ to a wet etchant comprising one or more of phosphoric acid, sulfuric acid, hydrochloric acid, nitric acid, or another material. In some embodiments, the sacrificial insulative structures 106, 106′ are removed by exposing the sacrificial insulative structures 106, 106′ to a so-called “wet nitride strip” comprising a wet etchant comprising phosphoric acid. In some embodiments, the sacrificial insulative structures 106, 106′ of the first stack structures 101′ and the second stack structures 101 may be removed simultaneously with the sacrificial insulative structures 106 of the third stack structures 105 through the slots 140.

After removal of the sacrificial insulative structures 106′ (FIG. 1), conductive structures 142′ may be formed between the neighboring insulative structures 104′ in the first stack structures 101′, resulting in tiers 143′ of the alternating insulative structures 104 and conductive structures 142′ of the first stack structures 101′. Furthermore, conductive structures 142 may be formed between the neighboring insulative structures 104 in the second stack structures 101, resulting in tiers 143 of the alternating insulative structures 104 and conductive structures 142 of the second stack structures 101. Additionally, conductive structures 144 may be formed between the neighboring insulative structures 104 in the third stack structures 105, resulting in tiers 145 of the alternating insulative structures 104 and conductive structures 144 of the third stack structures 105. The conductive structures 144 of the third stack structures 105 may comprise the same material composition as the conductive structures 142 of the second stack structures 101. The conductive structures 142 of the second stack structures 101 may function as local word line structures (e.g., local or word line plates). Lower portions of the third pillar structures 126 may be laterally adjacent to the conductive structures 144 of the third stack structures 105, and upper portions of the third pillar structures 126 may be located above the conductive structures 144 of the third stack structures 105. The conductive structures 144 of the third stack structures 105 may function as select gate structures, such as select gate drain (SGD) structures.

The conductive structures 142′ of the first stack structures 101′, the conductive structures 142 of the second stack structures 101, and the conductive structures 144 of the third stack structures 105 may each individually be formed of and include a conductive material. In some embodiments, at least one of the conductive structures 142′, 142, and 144 comprise tungsten. In other embodiments, at least one of the conductive structures 142′, 142, and 144 comprise conductively doped polysilicon.

In some embodiments, the conductive structures 142′, 142 of the first and second stack structures 101′, 101 may include a conductive liner material (not shown) around the conductive structures 142′, 142 such as between the conductive structures 142′, 142 and the insulative structures 104′, 104. In addition, the conductive structures 144 of the third stack structures 105 may include a conductive liner material (not shown) around the conductive structures 144, such as between the around the conductive structures 144 and the insulative structures 104. The conductive liner material may comprise, for example, a seed material from which the conductive structures 142′, 142, and 144 may be formed. The conductive liner material may be formed of and include, for example, a metal (e.g., titanium, tantalum), a metal nitride (e.g., tungsten nitride, titanium nitride, tantalum nitride), or another material. In some embodiments, the conductive liner material comprises titanium nitride.

Formation of the conductive structures 142′, 142 may form strings 160 of memory cells 162 extending through the first and second stack structures 101′, 101. The memory cells 162 of the strings 160 may be located at intersections of the first pillar structure 110′ and the conductive structures 142′, and at intersections of the second pillar structure 110 and the conductive structures 142. The memory cells 162 may individually include a portion of one of the first pillar structure 110′ and a portion of one of the conductive structures 142′, and a portion of one of the second pillar structure 110 and a portion of one of the conductive structures 142. Vertically neighboring memory cells 162 of the strings 160 may be separated from each other by one of the insulative structures 104′, 104.

After forming the conductive structures 142′, 142 and 144, the slots 140 may be filled with a conductive material to form an inter-block pillar structure 146 extending through the first stack structures 101′, the second stack structures 101, and the third stack structures 105. Accordingly, the inter-block pillar structure 146 may physically separate neighboring (e.g., adjacent) blocks 180 of the electronic device 100. Non-limiting examples of the material suitable for the inter-block pillar structure 146 include one or more of an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride); an oxynitride material (e.g., silicon oxynitride); a dielectric carbon nitride material (e.g., silicon carbon nitride); a dielectric carboxynitride material (e.g., silicon carboxynitride); polycarbon; spin-on carbon; or combinations thereof.

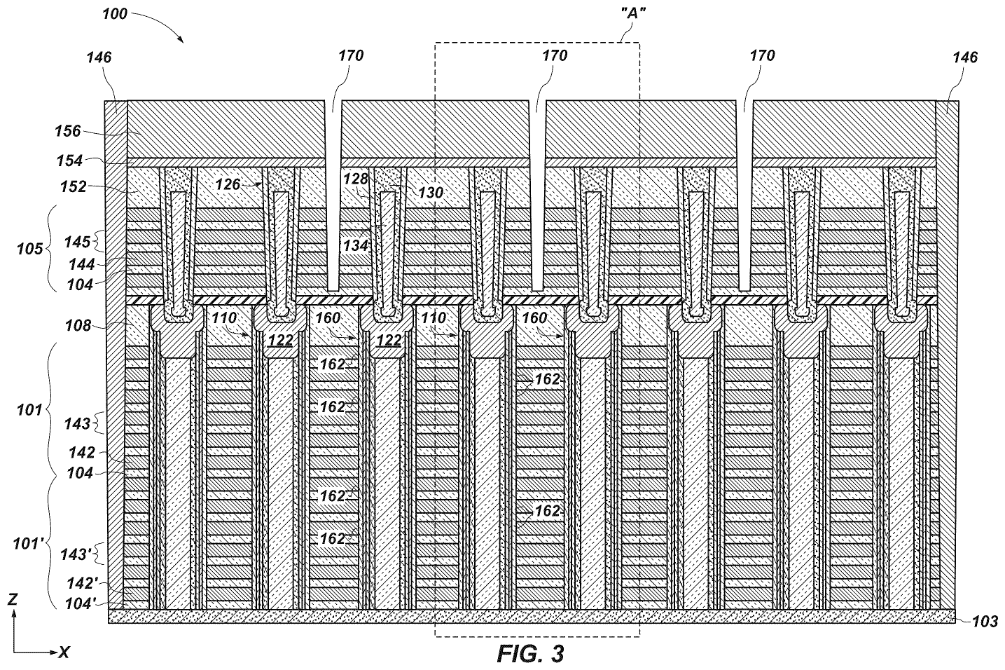

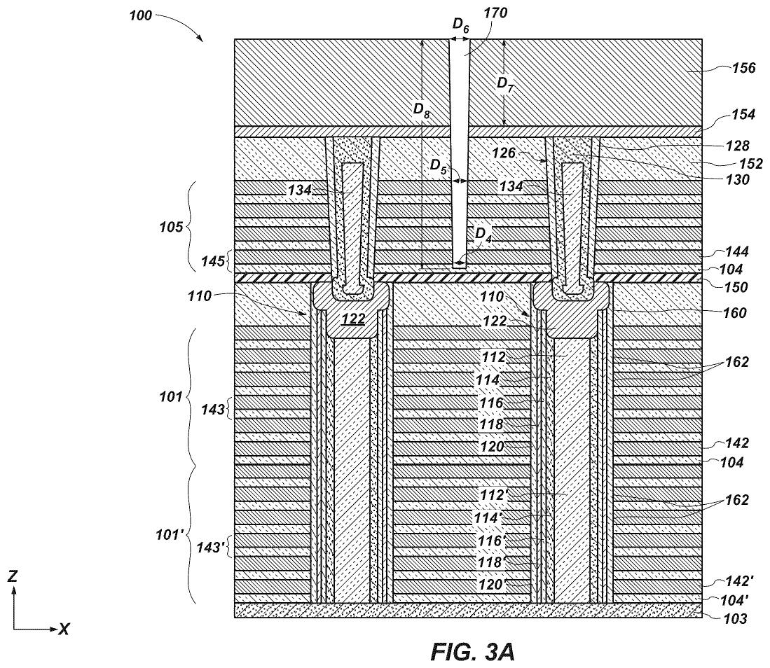

Referring to FIG. 3, openings 170 may be formed through the uppermost insulative material 156, the barrier material 154, the upper insulative material 152, and at least portions of the tiers 145 of the third stack structure 105, with sidewalls of these materials defining the openings 170. For example, the openings 170 may be formed by removing portions of the uppermost insulative material 156, the barrier material 154 and the upper insulative material 152, as well as portions of the insulative structures 104 and the conductive structure 144, between some of the neighboring third pillar structures 126. In some embodiments, the openings 170 may be substantially centered between the neighboring third pillar structures 126. The portions of the uppermost insulative material 156, the barrier material 154, the upper insulative material 152, as well as the portions of the insulative structures 104 and the conductive structure 144 in the tiers 145 may, for example, be removed by one or more material removal processes (e.g., a single etch process). The openings 170 may be formed (e.g., patterned) using substantially linear (e.g., substantially straight) openings in a resist material (e.g., a photoresist material, a mask material) (not shown) in the Y-direction.

In some embodiments, the openings 170 terminate at the upper surface of the etch stop material 150. In some embodiments, the openings 170 terminate within a lowermost one of the tiers 145 of the third stack structure 105. The openings 170 may segment the conductive structures 144 of the tiers 145 of the third stack structure 105 into different portions such that the conductive structures 144 are not substantially continuous within the blocks 180. Rather, such conductive structures 144 may be segmented by the openings 170, forming sub-blocks. In other words, the openings 170 may physically separate neighboring (e.g., adjacent) sub-blocks within the blocks 180 of the electronic device 100.

FIG. 3A is an enlarged view of the area labeled “A” in FIG. 3. A dimension D₄ (e.g., width) of a lower portion of the openings 170 may be within a range of from about 5 nm to about 80 nm, such as from about 5 nm to about 10 nm, from about 10 nm to about 20 nm, from about 10 nm to about 40 nm, from about 20 nm to about 40 nm, from about 40 nm to about 60 nm, from about 60 nm to about 80 nm, from about 15 nm to about 40 nm, from about 15 nm to about 30 nm, from about 20 nm to about 50 nm, from about 20 nm to about 40 nm, or from about 20 nm to about 30 nm. In some embodiments, the dimension D₄ may be about 25 nm. However, the disclosure is not so limited and the dimension D₄ may be different than those described.

A dimension D₅ (e.g., width) of the opening 170 at an intersection with the uppermost tiers 145 of the third stack structure 105 may be within a range of from about 20 nm to about 140 nm, such as from about 20 nm to about 80 nm, from about 20 nm to about 60 nm, from about 20 nm to about 50 nm, from about 20 nm to about 40 nm, from about 30 nm to about 60 nm, from about 30 nm to about 50 nm, from about 35 nm to about 50 nm, from about 40 nm to about 60 nm, from about 60 nm to about 80 nm, from about 80 nm to about 100 nm, from about 100 nm to about 120 nm, or from about 120 nm to about 140 nm. In some embodiments, the dimension D₅ is about 35 nm. However, the disclosure is not so limited and the dimension D₅ may be different than those described.

A dimension D₆ (e.g., a diameter) of an uppermost portion of the openings 170 may be within a range from about 30 nm to about 90 nm, such as from about 30 nm to about 80 nm, from about 40 nm to about 80 nm, from about 40 nm to about 60 nm, from about 40 nm to about 70 nm, from about 50 nm to about 80 nm, or from about 50 nm to about 70 nm. In some embodiments, the dimension D₆ is within from about 50 nm to about 60 nm. However, the disclosure is not so limited and the dimension D₇ may be different than those described. In some embodiments, the dimension D₆ is larger than the dimension D₅, and dimension D₅ is larger than the dimension D₄; therefore, sidewalls of the openings 170 may exhibit a tapered (e.g., sloped) shape with respect to a major surface of the source 103.

Furthermore, a dimension D₇ (e.g., thickness) of the uppermost insulative material 156 may be within a range from about 100 nm to about 300 nm, such as from about 100 nm to about 250 nm, from about 150 nm to about 300 nm, from about 150 nm to about 250 nm, from about 200 nm to about 300 nm, or from about 200 nm to about 250 nm. In some embodiments, the dimension D₇ is about 220 nm. However, the disclosure is not so limited and the dimension D₇ may be different than those described.

A dimension D₈ is a depth in the vertical direction of the openings 170. The dimension D₈ may be within a range from about 400 nm to about 750 nm, such as from about 400 nm to about 700 nm, from about 400 nm to about 600 nm, from about 400 nm to about 550 nm, from about 450 nm to about 600 nm, or from about 500 nm to about 600 nm. In some embodiments, the dimension D₈ is about 550 nm. However, the disclosure is not so limited, and the dimension D₈ may be different than those described.

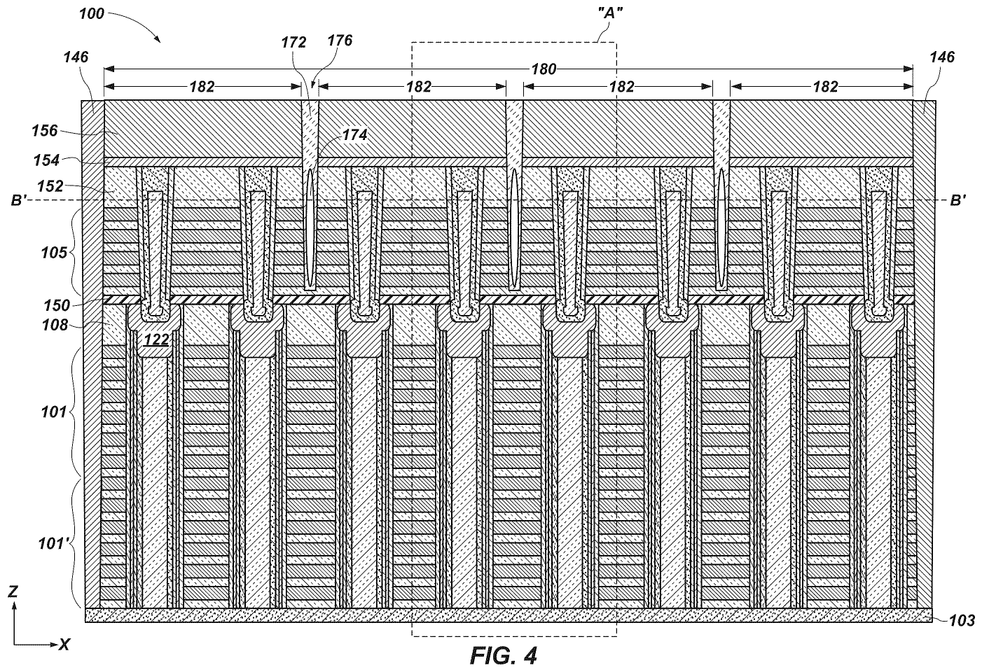

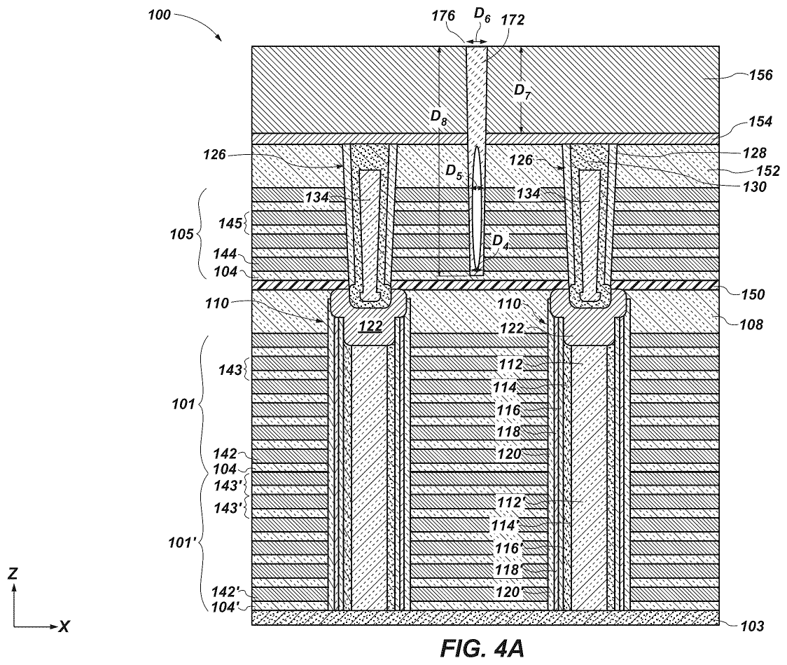

Referring to FIG. 4, a dielectric material 172 may be non-conformally formed within the openings 170, with at least a portion of (e.g., a majority of) the openings 170 remaining as an air gap 174 to form an isolation structure 176. In some embodiments, the dielectric material 172 may be non-conformally formed within the openings 170 using physical vapor deposition (PVD) technique. Alternatively, the dielectric material 172 may be formed within a lower portion of the openings 170 by PVD and subsequently grown on an upper portion of the openings 170 to form the air gap 174. The dielectric material 172 may be formed on sidewalls of the uppermost insulative material 156, the barrier material 154, and the upper insulative material 152, with less or substantially no dielectric material 172 formed on sidewalls of the tiers 145 or the bottom of the openings 170. The dielectric material 172 may be formed on the sidewalls without substantially completely filling the openings 170 so that the dielectric material 172 pinches off within the openings 170. The deposited dielectric material 172, therefore, within the openings 170 defines the air gap 174. As shown in FIG. 4 and FIG. 4A, the air gap 174 may be laterally adjacent to the tiers 145, with a portion of the air gap 174 laterally adjacent to the upper insulative material 152. However, the air gap 174 may also be laterally adjacent to the uppermost insulative material 156 and the barrier material 154 depending on the size of the openings 170, the material used as the dielectric material 172, and the deposition technique. While FIG. 4 and FIG. 4A show the air gap 174 as an elongated circle shape, the disclosure is not so limited and additional configurations of the air gap 174 may be contemplated.

The dielectric material 172 may be formed of and include, for example, an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride), an oxynitride material (e.g., silicon oxynitride), a dielectric carbon nitride material (e.g., silicon carbon nitride), a dielectric carboxynitride material (e.g., silicon carboxynitride), or combinations thereof. In some embodiments, the dielectric material 172 comprises a nitride material (e.g., silicon nitride), although other materials may be contemplated, so long as the dielectric material 172 exhibits etch selectivity relative to surrounding materials for subsequent process acts.

The isolation structure 176 may isolate (e.g., electrically isolate) conductive components from one another, such as isolating some conductive structures 144 of the tiers 145 from other conductive structures 144 of the tiers 145. The isolation structure 176 may extend through the uppermost insulative material 156, the barrier material 154, the upper insulative material 152, and at least portions of the tiers 145 of the third stack structure 105. In some embodiments, the isolation structure 176 may be substantially centered between the neighboring third pillar structures 126. The isolation structure 176 may segment the blocks 180 of the electronic device 100 into sub-blocks 182, each defined within horizontal boundaries between neighboring isolation structures 176.

In some embodiments, the isolation structure 176 terminates at the upper surface of the etch stop material 150. In some embodiments, the isolation structure 176 terminates within a lowermost one of the tiers 145 of the third stack structure 105. The isolation structure 176 segments the conductive structures 144 of the tiers 145 of the third stack structure 105 into different portions such that the conductive structures 144 are not substantially continuous within the blocks 180. In other words, the isolation structure 176 may physically separate neighboring (e.g., adjacent) sub-blocks 182 within the blocks 180 of the electronic device 100.

The isolation structures 176 include the air gap 174 therein. The air gap 174 in the isolation structures 176 may represent at least about 50% by volume based on a total volume of the isolation structures 176, such as more than about 50% by volume, more than about 55% by volume, more than about 60% by volume, more than about 65% by volume, more than about 70% by volume, more than about 75% by volume, more than about 80% by volume, more than about 85% by volume, more than about 90% by volume, or more than about 95% by volume. With the air gap 174 in the isolation structures 176, the isolation structures 176 may exhibit different stress characteristics than if the opening 170 was substantially completely filled with the dielectric material 172.

The dielectric constant of air is about 1; while the dielectric constants of silicon oxide and silicon nitride are 3.9 and 7, respectively. Air has a lower dielectric constant than conventional dielectric materials (e.g., silicon oxide, silicon nitride); therefore, the isolation structure 176 comprising the air gap 174 therein may provide a higher degree of isolation between sub-blocks 182 of the electronic device 100 compared to if the dielectric material 172 completely filled the opening 170 (e.g., without any air gap therein). Since the isolation structure 176 is formed by non-conformally depositing the dielectric material 172 in the openings 170, dimensions of the openings 170 may be smaller and the isolation structure 176 comprising an air gap 174 may be fabricated to exhibit a small critical dimension compared to a conventional electronic device in which the opening is substantially completely filled with conventional dielectric materials. With the small dimensions of the openings 170, the isolation structure 176 may be formed more easily between neighboring third pillar structures 126, reducing the likelihood of misalignment due to block bending. Having the air gap 174 in the isolation structure 176 may also result in reduced shorting. The electronic device 100 according to embodiments of the disclosure may, however, provide at least a similar degree of isolation between sub-blocks 182 compared to a conventional electronic device. This, for example, allows for the fabrication of electronic devices 100 with an increased memory density.

In addition to providing electrical isolation, electrical performance of the electronic device 100 including the air gap 174 in the isolation structures 176 may be improved relative to a conventional electronic device lacking such an air gap. The electronic device 100 including the air gap 174 may, for example, have reduced capacitance and reduced parasitic coupling.

While FIG. 4 and FIG. 4A show the air gap 174 in an elongated circle shape, the disclosure is not so limited and additional configurations of the air gap 174 may be contemplated.

As shown in FIG. 4A, isolation structures 176 may be located between neighboring third pillar structure 126 that are substantially horizontally aligned in each of the X-direction and the Y-direction (e.g., that are concentric) with corresponding strings 160 of memory cells 162 directly underneath the third pillar structure 126.

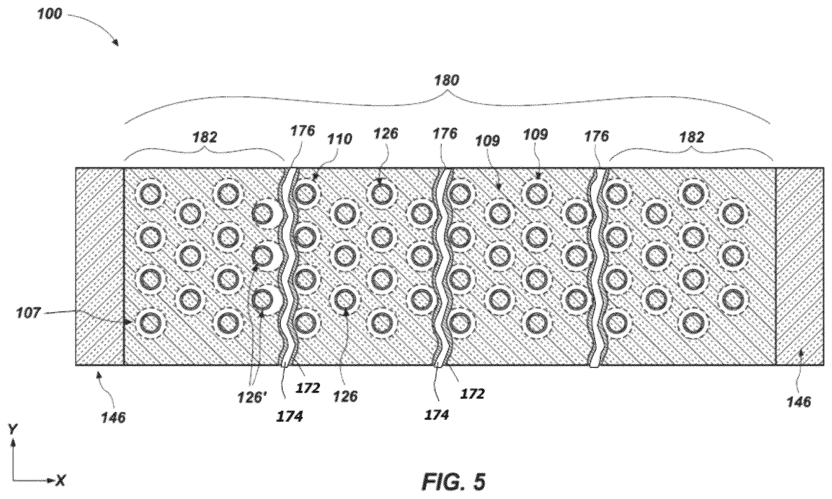

FIG. 5 is a top-down view taken along line B-B′ of the electronic device 100 of FIG. 4. For clarity and ease of understanding the drawings and associated description, surrounding materials including the uppermost insulative material 156 and the barrier material 154 are absent in FIG. 5.

The electronic device 100 may include the conductive structures 146 that are horizontally spaced from each other (e.g., in the X-direction) by the first pillar structures 110′, the second pillar structures 110, and the third pillar structures 126. The electronic device 100 may be divided into blocks 180 between horizontally neighboring conductive structures 146 (e.g., in the X-direction). Each block 180 may be divided into sub-blocks 182 between horizontally neighboring isolation structures 176 (e.g., in the X-direction). The isolation structure 176 is composed of a dielectric material 172 and an air gap 174 defined by and/or surrounded by the dielectric material 172. FIG. 5 shows that the dielectric material 172 of the isolation structure 176 has a substantially same lateral thickness (e.g., in the X-direction). However, the disclosure is not so limited and the dielectric material 172 of the isolation structure 176 may have a different lateral thickness throughout the electronic device 100 (e.g., in the Y-direction). Furthermore, FIG. 5 shows that the dielectric material 172 in each of the isolation structure 176 has a substantially same lateral thickness (e.g., in the X-direction). However, the disclosure is not so limited and the dielectric material 172 in each of the isolation structure 176 may have a different lateral thickness. While two of the conductive structures 146 are shown in FIG. 5 for clarity, the disclosure is not so limited, and the electronic device 100 may include a different number of the conductive structures 146. Furthermore, while three of the isolation structures 176 are shown in FIG. 5 for clarity, the disclosure is not so limited, and the electronic device 100 may include a different number of the isolation structures 176.

As shown in FIG. 5, each sub-block 182 includes the first pillar structures 110′, the second pillar structures 110, and the third pillar structures 126. Each of the sub-blocks 182 includes rows 107 of the first pillar structures 110′, the second pillar structures 110, and the third pillar structures 126 extending in a first horizontal (e.g., lateral) direction (e.g., in the X-direction), and columns 109 extending in a second horizontal direction (e.g., in the Y-direction). A lateral dimension (e.g., a width, a diameter in a horizontal direction) of one or more of the conductive structures 146 may be relatively larger than a lateral dimension of one or more (e.g., each) of the first pillar structure 110′, the second pillar structure 110, and the third pillar structure 126. The first pillar structure 110′ and the second pillar structure 110 are illustrated in broken lines to indicate that they are located below the third pillar structure 126. In some embodiments, each of the third pillar structure 126 is substantially horizontally aligned with the first pillar structure 110′ and the second pillar structure 110 (e.g., in each of the X-direction and the Y-direction) with a center of the vertically underlying (e.g., in the Z-direction). In other embodiments, at least some of the second pillar structure 110 may be horizontally offset in at least one horizontal direction (e.g., the X-direction) from the center of the underlying second pillar structure 110, without being centered over a respective second pillar structure 110. Each of the first pillar structure 110′, the second pillar structure 110, and the third pillar structure 126, 126′ may individually exhibit a substantially circular cross-sectional shape, as shown in FIG. 5. However, the disclosure is not so limited, and additional configurations may be contemplated. For example, one or more of the first pillar structure 110′, the second pillar structure 110, and the third pillar structure 126, 126′ may individually exhibit a substantially rectangular cross-sectional shape (e.g., a substantially square cross-sectional shape).

The electronic device 100 may be subjected to further process act to form a complete electronic device, electronic system, or processor-based system containing the isolation structure 176.

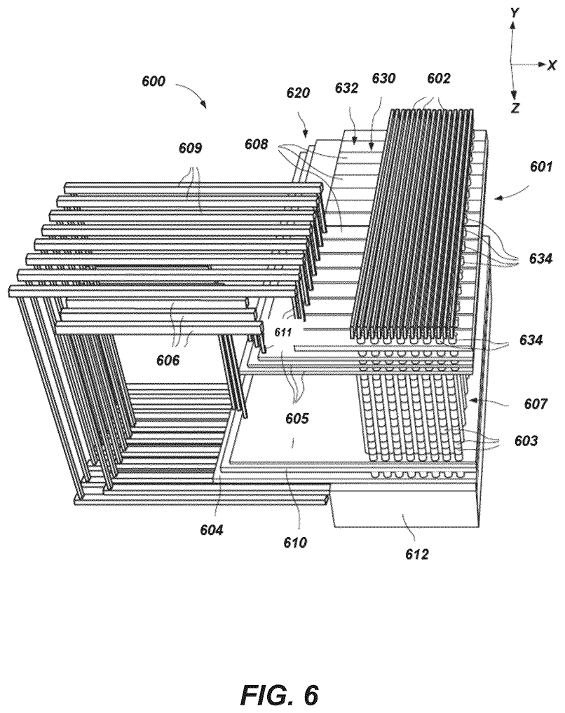

FIG. 6 illustrates a partial cutaway perspective view of a portion of an electronic device 600 (e.g., a microelectronic device, a memory device, such as a 3D NAND Flash memory device) including one or more electronic device structures 601 (e.g., a microelectronic device structure). The electronic device 600 may include one or more structures substantially similar to the electronic device 100 previously described with reference to FIG. 4. One or more electronic devices 100 including the inter-block pillar structure 146 segmenting the stack structures 101, 101′, 105 of the electronic devices into blocks 180, and the isolation structure comprising an air gap structure therein and segmenting the blocks 180 into sub-blocks 182 according to embodiments of the disclosure, may be present. As shown in FIG. 6, the electronic device structure 601 of the electronic device 600 may include a staircase structure 620 defining contact regions for connecting interconnect lines 606 to conductive structures 605 (e.g., corresponding to the conductive structures 142 (FIG. 4A)). The electronic device structure 601 may include vertical strings 607 (e.g., corresponding to the strings 160 (FIG. 4A)) of memory cells 603 (e.g., corresponding to the memory cells 162 (FIG. 4A)) that are coupled to each other in series. The vertical strings 607 may extend vertically (e.g., in the Z-direction) and orthogonally to conductive lines and the conductive structures 605, such as data lines 602, a source tier 604 (e.g., corresponding to the source 103 (FIG. 4A)), the conductive structures 605, the interconnect lines 606, first select gates 608 (e.g., upper select gates, drain select gates (SGDs)), such as the tiers 145 of the third stack structure 105 (FIG. 4A), select lines 609, and a second select gate 610 (e.g., a lower select gate, a source select gate (SGS)). The first select gates 608 may be horizontally divided (e.g., in the Y-direction) into multiple blocks 632 (e.g., corresponding to the blocks 180 (FIG. 4)) horizontally separated (e.g., in the Y-direction) from one another by slots 630 (e.g., corresponding to the inter-block pillar structure 146 (FIG. 4) and the isolation structure 176 (FIG. 4)).

Vertical conductive contacts 611 may electrically couple components to each other as shown. For example, the select lines 609 may be electrically coupled to the first select gates 608 and the interconnect lines 606 may be electrically coupled to the conductive structures 605. The electronic device 600 may also include a control unit 612 positioned under the memory array, which may include at least one of string driver circuitry, pass gates, circuitry for selecting gates, circuitry for selecting conductive lines (e.g., the data lines 602, the interconnect lines 606), circuitry for amplifying signals, and circuitry for sensing signals. The control unit 612 may be electrically coupled to the data lines 602, the source tier 604, the interconnect lines 606, the first select gates 608, and the second select gates 610, for example. In some embodiments, the control unit 612 includes CMOS (complementary metal-oxide-semiconductor) circuitry. In such embodiments, the control unit 612 may be characterized as having a “CMOS under Array” (“CuA”) configuration.

The first select gates 608 may extend horizontally in a first direction (e.g., the X-direction) and may be coupled to respective first groups of vertical strings 607 of memory cells 603 at a first end (e.g., an upper end) of the vertical strings 607. The second select gate 610 may be formed in a substantially planar configuration and may be coupled to the vertical strings 607 at a second, opposite end (e.g., a lower end) of the vertical strings 607 of memory cells 603.

The data lines 602 (e.g., digit lines, bit lines) may extend horizontally in a second direction (e.g., in the Y-direction) that is at an angle (e.g., perpendicular) to the first direction in which the first select gates 608 extend. Individual data lines 602 may be coupled to individual groups of the vertical strings 607 extending the second direction (e.g., the Y-direction) at the first end (e.g., the upper end) of the vertical strings 607 of the individual groups. Additional individual groups of the vertical strings 607 extending the first direction (e.g., the X-direction) and coupled to individual first select gates 608 may share a particular vertical string 607 thereof with individual group of vertical strings 607 coupled to an individual data line 602. Thus, an individual vertical string 607 of memory cells 603 may be selected at an intersection of an individual first select gate 608 and an individual data line 602. Accordingly, the first select gates 608 may be used for selecting memory cells 603 of the vertical strings 607 of memory cells 603.

The conductive structures 605 (e.g., word line word lines, such as the conductive structures 142 (FIG. 4A)) may extend in respective horizontal planes. The conductive structures 605 may be stacked vertically, such that each conductive structure 605 is coupled to at least some of the vertical strings 607 of memory cells 603, and the vertical strings 607 of the memory cells 603 extend vertically through the stack structure including the conductive structures 605. The conductive structures 605 may be coupled to or may form control gates of the memory cells 603.

The first select gates 608 and the second select gates 610 may operate to select a vertical string 607 of the memory cells 603 interposed between data lines 602 and the source tier 604. Thus, an individual memory cell 603 may be selected and electrically coupled to a data line 602 by operation of (e.g., by selecting) the appropriate first select gate 608, second select gate 610, and conductive structure 605 that are coupled to the particular memory cell 603.

The staircase structure 620 may be configured to provide electrical connection between the interconnect lines 606 and the conductive structures 605 through the vertical conductive contacts 611. In other words, an individual conductive structure 605 may be selected via an interconnect line 606 in electrical communication with a respective vertical conductive contact 611 in electrical communication with the conductive structure 605. The data lines 602 may be electrically coupled to the vertical strings 607 through conductive contact structures 634.

Thus, in accordance with embodiments of the disclosure, an electronic device comprises a first stack structure, a second stack structure adjacent to the first stack structure, a third stack structure adjacent to the second stack structure, an inter-block pillar structure extending vertically through the first, second, and third stack structures and segmenting the stack structures into blocks, and an isolation structure extending vertically through at least a portion of the third stack structure and segmenting the blocks into sub-blocks. The isolation structure comprises an air gap structure therein. The first stack structure comprises tiers of vertically alternating first conductive structures and first insulative structures. The second stack structure comprises tiers of vertically alternating second conductive structures and second insulative structures. The third stack structure comprises tiers of vertically alternating third conductive structures and third insulative structures. In some of these embodiments, the first insulative structures have the same material composition as the second insulative structures and/or the third insulative structures. In some other embodiments, the first conductive structures have the same material composition as the second conductive structures and/or the third conductive structures. In yet some other embodiments, the first insulative structures have same material composition as the second insulative structures and/or the third insulative structures, and the first conductive structures have same material composition as the second conductive structures and/or the third conductive structures. The electronic device also comprises a first pillar structure extending vertically through the first stack structure and a second pillar structure extending vertically through the second stack structure. Each of the first and second pillar structures comprises strings of memory cells. The electronic device further comprises a third pillar structure extending vertically through the third stack structure and adjacent to the second pillar structure.

Thus, in accordance with additional embodiments of the disclosure, an electronic device comprises a stack structure, an inter-block pillar structure extending through the stack structure and segmenting the stack structure into blocks, and an isolation structure segmenting the blocks of the stack structure into sub-blocks. The isolation structure comprises an air gap therein, and each of the sub-blocks is defined within horizontal boundaries between the neighboring isolation structures. In some embodiments, the stack structure comprises a first stack structure, a second additional stack structure overlying the first stack structure, and a third stack structure overlying the second stack structure. In some embodiments, the electronic device further comprises a memory pillar extending through the first and second stack structures, and defining memory cells at intersections of the memory pillar and the vertically alternating conductive structures of the first and second stack structures. In some embodiments, the electronic device also comprises a conductive pillar extending vertically through the third stack structure.

Thus, in accordance with additional embodiments of the disclosure, a method of forming an electronic device comprises forming a stacked structure, and forming an inter-block pillar structure through the first, second, and third stack structures and segmenting the first, second, and third stack structures into blocks. The stacked structure comprises a first stack structure overlying a source, a second stack structure overlying the first stack structure, and a third stack structure overlying the second stack structure, the second stack structure positioned vertically between the first and third stack structure. Each of the first, second, and third stack structures comprises tiers of vertically alternating conductive structures and insulative structures. The stack structure further comprises strings of memory cells extending vertically through the first and second stack structures, the strings of memory cells individually comprising a channel material extending vertically through the first and second stack structures. The stack structure also comprises a conductive pillar structure overlying the strings of memory cells, the conductive pillar structure extending vertically through the third stack structure. The method also comprises forming an opening between some laterally adjacent conductive pillar structures, and forming an isolation structure in the opening. The isolation structure comprises a dielectric material surrounding an air gap and segments the blocks of the stack structure into sub-blocks.

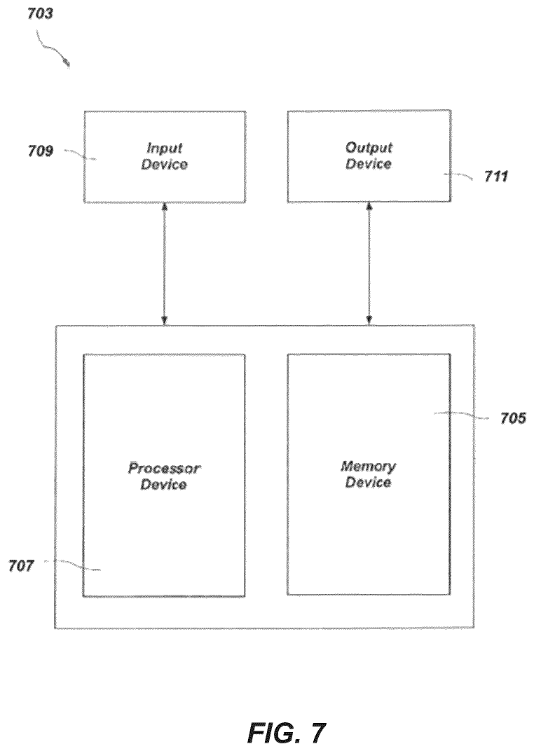

Electronic devices (e.g., the electronic device 100) including the inter-block pillar structure 146 segmenting the stack structures 101, 105 of the electronic devices into blocks 180, and the isolation structure comprising an air gap structure therein and segmenting the blocks 180 into sub-blocks 182 according to embodiments of the disclosure, may be used in embodiments of electronic systems of the disclosure. For example, FIG. 7 is a block diagram of an electronic system 703, in accordance with embodiments of the disclosure. The electronic system 703 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 703 includes at least one memory device 705. The memory device 705 may include, for example, one or more electronic devices (e.g., one or more electronic devices 100 previously described with reference to FIGS. 4 and 5) including the inter-block pillar structure 146 segmenting the stack structures 101, 101′, 105 of the electronic device into blocks 180, and the isolation structure comprising an air gap structure therein and segmenting the blocks 180 into sub-blocks 182.

The electronic system 703 may further include at least one electronic signal processor device 707 (often referred to as a “microprocessor”). The electronic signal processor device 707 may optionally include an embodiment of an electronic device (e.g., the electronic device 100 previously described with reference to FIGS. 4 and 5). The electronic system 703 may further include one or more input devices 709 for inputting information into the electronic system 703 by a user, such as, for example, a mouse or other pointing device, a keyboard, a touchpad, a button, or a control panel. The electronic system 703 may further include one or more output devices 711 for outputting information (e.g., visual or audio output) to a user such as, for example, a monitor, a display, a printer, an audio output jack, a speaker, etc. In some embodiments, the input device 709 and the output device 711 may comprise a single touchscreen device that can be used both to input information to the electronic system 703 and to output visual information to a user. The input device 709 and the output device 711 may communicate electrically with one or more of the memory device 705 and the electronic signal processor device 707.

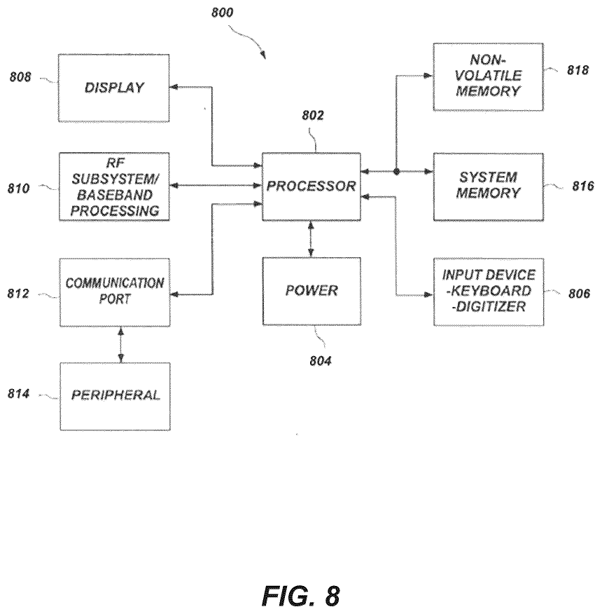

With reference to FIG. 8, depicted is a processor-based system 800. The processor-based system 800 may include various electronic devices (e.g., one or more electronic devices 100) manufactured in accordance with embodiments of the present disclosure. The processor-based system 800 may be any of a variety of types such as a computer, pager, cellular phone, personal organizer, control circuit, or other electronic device. The processor-based system 800 may include one or more processors 802, such as a microprocessor, to control the processing of system functions and requests in the processor-based system 800. The processor 802 and other subcomponents of the processor-based system 800 may include electronic devices (e.g., the electronic device 100) manufactured in accordance with embodiments of the present disclosure.

The processor-based system 800 may include a power supply 804 in operable communication with the processor 802. For example, if the processor-based system 800 is a portable system, the power supply 804 may include one or more of a fuel cell, a power scavenging device, permanent batteries, replaceable batteries, and rechargeable batteries. The power supply 804 may also include an AC adapter; therefore, the processor-based system 800 may be plugged into a wall outlet, for example. The power supply 804 may also include a DC adapter such that the processor-based system 800 may be plugged into a vehicle cigarette lighter or a vehicle power port, for example.

Various other electronic devices may be coupled to the processor 802 depending on the functions that the processor-based system 800 performs. For example, a user interface 806 may be coupled to the processor 802. The user interface 806 may include input devices such as buttons, switches, a keyboard, a light pen, a mouse, a digitizer and stylus, a touch screen, a voice recognition system, a microphone, or a combination thereof. A display 808 may also be coupled to the processor 802. The display 808 may include an LCD display, an SED display, a CRT display, a DLP display, a plasma display, an OLED display, an LED display, a three-dimensional projection, an audio display, or a combination thereof. Furthermore, an RF sub-system/baseband processor 810 may also be coupled to the processor 802. The RF sub-system/baseband processor 810 may include an antenna that is coupled to an RF receiver and to an RF transmitter (not shown). A communication port 812, or more than one communication port 812, may also be coupled to the processor 802. The communication port 812 may be adapted to be coupled to one or more peripheral devices 814, such as a modem, a printer, a computer, a scanner, or a camera, or to a network, such as a local area network, remote area network, intranet, or the Internet, for example.

The processor 802 may control the processor-based system 800 by implementing software programs stored in the memory. The software programs may include an operating system, database software, drafting software, word processing software, media editing software, or media playing software, for example. The memory is operably coupled to the processor 802 to store and facilitate execution of various programs. For example, the processor 802 may be coupled to system memory 816, which may include one or more of spin torque transfer magnetic random access memory (STT-MRAM), magnetic random access memory (MRAM), dynamic random access memory (DRAM), static random access memory (SRAM), racetrack memory, and other known memory types. The system memory 816 may include volatile memory, non-volatile memory, or a combination thereof. The system memory 816 is typically large so that it can store dynamically loaded applications and data. In some embodiments, the system memory 816 may include semiconductor devices, such as the electronic devices (e.g., the electronic device 100) described above, or a combination thereof.

The processor 802 may also be coupled to non-volatile memory 818, which is not to suggest that system memory 816 is necessarily volatile. The non-volatile memory 818 may include one or more of STT-MRAM, MRAM, read-only memory (ROM) such as an EPROM, resistive read-only memory (RROM), and flash memory to be used in conjunction with the system memory 816. The size of the non-volatile memory 818 is typically selected to be just large enough to store any necessary operating system, application programs, and fixed data. Additionally, the non-volatile memory 818 may include a high-capacity memory such as disk drive memory, such as a hybrid-drive including resistive memory or other types of non-volatile solid-state memory, for example. The non-volatile memory 818 may include electronic devices, such as the electronic devices (e.g., the electronic device 100) described above, or a combination thereof.

Thus, in accordance with embodiments of the disclosure a system comprises a processor operably coupled to an input device and an output device, and electronic devices operably coupled to the processor. The electronic devices comprise an inter-block pillar structure segmenting the stack structures of the electronic device into blocks, and the isolation structure comprising an air gap structure therein and segmenting the blocks into sub-blocks.

The electronic devices and systems of the disclosure advantageously facilitate one or more of improved simplicity, greater packaging density, and increased miniaturization of components as compared to conventional electronic devices and conventional systems. The methods of the disclosure facilitate the formation of devices (e.g., apparatuses, microelectronic devices, memory devices) and systems (e.g., electronic systems) having one or more of improved performance, reliability, and durability, lower costs, increased yield, increased miniaturization of components, improved pattern quality, and greater packaging density as compared to conventional devices (e.g., conventional apparatuses, conventional electronic devices, conventional memory devices) and conventional systems (e.g., conventional electronic systems).

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device, comprising:
a first stack structure comprising tiers of vertically alternating first conductive structures and first insulative structures;
a second stack structure adjacent to the first stack structure and comprising tiers of vertically alternating second conductive structures and second insulative structures;
a third stack structure adjacent to the second stack structure and comprising tiers of vertically alternating third conductive structures and third insulative structures;
a first pillar structure extending vertically through the first stack structure, the first pillar structure comprising strings of memory cells;
a second pillar structure extending vertically through the second stack structure and adjacent to the first pillar structure, the second pillar structure comprising strings of memory cells;
a third pillar structure extending vertically through the third stack structure and adjacent to the second pillar structure;
an inter-block pillar structure extending vertically through the first, second, and third stack structures and segmenting the first, second, and third stack structures into blocks; and
an isolation structure extending vertically through at least a portion of the third stack structure and segmenting the blocks into sub-blocks, the isolation structure comprising an air gap therein.

2. The electronic device of claim 1, wherein the air gap represents at least 50% by volume of the isolation structure.

3. The electronic device of claim 1, wherein the isolation structure is interposed laterally between neighboring third pillar structures.

4. The electronic device of claim 1, wherein the isolation structure exhibits a tapered profile with an upper portion exhibiting a greater critical dimension than a lower portion thereof.

5. The electronic device of claim 1, wherein the isolation structure has a depth in a range of from about 400 nm to about 750 nm, and a width at an uppermost portion in a range of from about 30 nm to about 90 nm.

6. The electronic device of claim 1, wherein the isolation structure has a width at an intersection with an uppermost tier of the third stack structure in a range of from about 20 nm to about 140 nm, and a width of a lower portion in a range of from about 5 nm to about 80 nm.

7. The electronic device of claim 1, further comprising a barrier material over the third stack structure and an uppermost insulative material over the barrier material, the uppermost insulative material having a vertical dimension in a range of from about 100 nm to about 300 nm.

8. The electronic device of claim 7, wherein the isolation structure extends through the uppermost insulative material, the barrier material, and the at least a portion of the third stack structure.

9. The electronic device of claim 1, further comprising an etch stop material between the second and third stack structures, the isolation structure extending vertically through the third stack structure and to an upper surface of the etch stop material.

10. The electronic device of claim 1, wherein the isolation structure terminates within a lowermost one of the tiers of the third stack structure.

11. The electronic device of claim 1, wherein the isolation structure segments the third conductive structures of the tiers of the third stack structure into different portions such that the third conductive structures are not continuous within the blocks.

12. An electronic device, comprising:
a stack structure comprising a vertically alternating sequence of insulative structures and conductive structures;
an inter-block pillar structure extending through the stack structure and segmenting the stack structure into blocks; and
an isolation structure comprising an air gap therein, the isolation structure segmenting the blocks of the stack structure into sub-blocks, each of the sub-blocks defined within horizontal boundaries between neighboring isolation structures.

13. The device of claim 12, wherein the stack structure comprises a first stack structure, a second stack structure overlying the first stack structure, and a third stack structure overlying the second stack structure, and
wherein the electronic device further comprises:
a memory pillar extending through the first and second stack structures, and defining memory cells at intersections of the memory pillar and the vertically alternating conductive structures of the first and second stack structures; and
a conductive pillar extending vertically through the third stack structure.

14. The device of claim 13, wherein the isolation structure is positioned substantially centered between neighboring conductive pillar structures.

15. The device of claim 12, wherein the isolation structure further comprises a dielectric material surrounding the air gap.

16. A method of forming an electronic device, comprising:
forming a stack structure comprising a first stack structure overlying a source, a second stack structure overlying the first stack structure, and a third stack structure overlying the second stack structure, the second stack structure positioned vertically between the first and third stack structures, each of the first, second, and third stack structures comprising tiers of vertically alternating conductive structures and insulative structures, the stack structure comprising:
strings of memory cells extending vertically through the first and second stack structures, the strings of memory cells individually comprising a channel material extending vertically through the first and second stack structures; and
a conductive pillar structure overlying the strings of memory cells, the conductive pillar structure extending vertically through the third stack structure;
forming an inter-block pillar structure through the first, second, and third stack structures and segmenting the first, second, and third stack structures into blocks;
forming an opening between some laterally adjacent conductive pillar structures; and
forming an isolation structure in the opening, the isolation structure comprising a dielectric material surrounding an air gap, the isolation structure segmenting the blocks into sub-blocks.

17. The method of claim 16, wherein forming the isolation structure in the opening comprises non-conformally filling the opening with the dielectric material.

18. The method of claim 16, wherein forming the isolation structure in the opening comprises depositing the dielectric material in the opening using physical vapor deposition technique.

19. The method of claim 16, wherein forming the isolation structure comprises separating some of the conductive structures of the tiers of the third stack structure from other conductive structures of the same tiers of the third stack structure.

20. The method of claim 16, wherein forming the isolation structure comprises forming the air gap defined by sidewalls of the dielectric material, the air gap extending to a lowermost tier of the tiers of the third stack structure.
